(19) United States
(12) Patent Application Publication
(10) Pub. No.: US 2011/0146724 A1
(43) Pub. Date: Jun. 23, 2011

(54) PHOTORESIST STRIPPING SOLUTIONS

(75) Inventor: WAI MUN LEE, MILPITAS, CA (US)

(73) Assignee: Mr. WAI MUN LEE, MILPITAS, CA (US)

(21) Appl. No.: 12/900,342

(22) Filed: Oct. 7, 2010

Related U.S. Application Data
(60) Provisional application No. 61/288,282, filed on Dec. 19, 2009.

(51) Int. Cl. B08B 3/00; C11D 3/60; G03F 7/42

(52) U.S. Cl. 134/26; 510/175; 510/176

(57) ABSTRACT

The present invention discloses a photoresist stripper for removing positive and negative tone photoresist, bonding adhesive, ink mark and post etch residue etc. from semiconductor substrates. The photoresist stripper comprises:
a) one or more organic sulfonic acids with a structure of

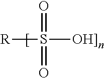

where R can be alkyl, substituted alkyl, aryl, substituted aryl and alkylaryl, and n is 1 or higher; and
b) one or more alkanolamine; one or more alkanolamine with the structure of

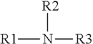

wherein R1 and R2 can be H, alkyl, aryl, alkylaryl, arylalkyl, alkyl alcohol, aryl alcohol, alkyaryl alcohol or arylalkyl alcohol and R3 is alkyl alcohol, aryl alcohol, alkyaryl alcohol or arylalkyl alcohol or the like.
c) Optionally, one or more halogen free organic solvents.
d) Optionally, one or more corrosion inhibitors

Optionally, the photoresist stripper further comprises other surfactants.

### CROSS-REFERENCE TO RELATED APPLICATIONS

The present application is a non-provisional application which claims priority from U.S. Provisional Appl. No. 61/288,282, filed Dec. 19, 2009, and is incorporated herein by reference in its entirety.

### BACKGROUND OF THE INVENTION

During manufacture of semiconductors and semiconductor microcircuits, it is frequently necessary to coat the materials from which the semiconductors and microcircuits are manufactured with a polymeric organic substance, generally referred to as a photoresist, e.g., a substance which forms an etch resist upon exposure to light. These photoresists are used to protect selected areas of the surface of the substrate, e.g. silicon, SiO₂ or aluminum while such etchant selectively removes the substrate materials from the unprotected area of the substrate. Following completion of the etching operation and washing away of the residual etchant, it is necessary that the resist be removed from the protective surface to permit essential finishing operations. It is necessary in a photolithographic process that the photoresist material, following pattern delineation, be evenly and completely removed from all unexposed areas, in the case of positive resists, or exposed areas in the case of negative resists, so as to permit further lithographic operations. Even the partial remains of a resist in an area to be further patterned are undesirable. Also, undesired resist residues between patterned lines can have deleterious effects on subsequent processes, such as metallization, or cause undesirable surface states and charges.

A common method used in removing the photoresist from the substrate is by contacting the substrates with an organic stripper. Heretofore these organic strippers have been composed of various components whose purpose is to dissolve and/or lift-off the polymeric photoresist from the substrate.

However, these stripping solutions have heretofore usually contained chlorinated organic compounds which resulted in a distinct disadvantage due to the toxicity as well as pollution problems arising from their disposal.

It is highly desirable that stripping compositions be provided are effective and efficient for removal of photoresist coatings from the substrate without attacking the underlying metal surfaces.

It is also desirable that effective stripping compositions be provided are devoid of undesirable chlorinated solvents to be considered undesirable by regulatory agencies overseeing their production and use.

It is known that mixtures of aromatic solvent with an alkylarylsulfonic acid have 6-20 carbons effectively removing positive and negative tone photoresists, bonding adhesive, ink mark and post etch residue etc. are being used in semiconductor manufacturing. However, such mixtures causes corrosion of the metal surface substrates, such as aluminum and copper, which are being used as conducting wiring for the integrated devices.

Compositions and method of removing a resist or other material from a substrate using the stripping compositions have been developed, such as described in the followings and are herein being incorporated by reference in their entirety.

U.S. Pat. No. 4,215,005—discloses the use of hydrogen fluoride complexes to reduce aluminum corrosion during stripping to improve over stripping solutions cited in U.S. Pat. No. 4,165,294

U.S. Pat. No. 4,221,674—discloses the use of inhibitors system containing hydrogen fluoride and nitrile compound to enhance corrosion inhibition properties of the fluoride to further improve over stripping solutions cited in U.S. Pat. No. 4,215,005.

U.S. Pat. No. 4,395,348—discloses the use of catechol as corrosion inhibitor by heating the solution to 60° C. to dissolve the catechol into the solution prior using it for photoresist stripping.

U.S. Pat. No. 4,491,530—discloses the use of water soluble sulfone to suppress the “brown staining” which is a form of metal corrosion on aluminum metal surface [Col 5, lines 19-30].

U.S. Pat. No. 4,844,832—discloses the use of phenolic compounds in the stripping solution to achieve the stripping performance.

U.S. Pat. No. 5,728,664—discloses the use of alkyl phenol as corrosion inhibitor to improve stripper solutions cited in U.S. Pat. No. 4,992,108.

U.S. Pat. Nos. 6,475,292 and 6,660,460—discloses use of catechol as the preferred corrosion inhibitor.

U.S. Pat. Nos. 4,770,713 and 4,403,029 disclose cleaning compositions which include N-methyl-2-pyrrolidone, N,N dimethylacetamide solvents and an alkanolamine. The use of N-methyl-2-pyrrolidone or N,N Dimethylacetamide does not provide a broad spectrum of stripping as is capable with the composition of the invention in removing negative tone photoresist comprising neoprene polymeric composition.

U.S. Pat. No. 4,617,251 to Sizensky discloses a stripping composition which is prepared with a select amine and an organic polar solvent. The composition is formed utilizing from about 2 to about 98% by weight of amine compound and about 98 to about 2% of an organic polar solvent. Such composition does not provide a broad spectrum of stripping as is capable with the composition of the invention in removing negative tone photoresist comprising neoprene polymeric composition.

It is another object of this invention to provide a photoresist stripping solution comprising an organic sulfonic acid and a organic solvent which is essentially free chlorinated organic compounds which can be used at a wide range of operating conditions and at lower temperatures without corrosion of the semiconductor substrate.

It is an object of the present invention to provide a photoresist stripping composition comprising of a mixture of an organic sulfonic acid, an alkanolamine and an organic solvent which can be used at a wide range of operating conditions and at lower temperatures without corrosion of the semiconductor substrate.

The preferred range pH of the composition is from about 0.5 to about 6.

The material to be stripped is typically contacted with the present compositions for a period of time sufficient to at least partially remove the material, preferably for a period of time to substantially remove the material, and more preferably for a period of time to completely remove the material. The contact time of the present compositions with the material to be stripped will vary, depending upon the exact stripper composition as well as the material to be stripped.

For example, the material to be removed may be contacted with the present compositions for up to about 60 minutes, preferably from about 5 seconds to about 45 minutes, and more preferably from about 15 seconds to about 35 minutes. In removing material, the compositions of the present invention may be used at room temperature or may be heated. Such heating has the advantage of shortening the time required for complete removal of the material. Typically, the compositions of the present invention are heated at a temperature of about 30° C. to about 120° C., and preferably about 40° C. to about 95° C.

### SUMMARY OF THE INVENTION

The present invention relates to a photoresist stripper for removing positive and negative tone photoresist, bonding adhesive and ink mark, etc. from semiconductor substrates. The photoresist stripper comprises a mixture of one or more organic sulfonic acid(s), one or more alkanolamine(s), and one or more organic solvent(s), and the method includes mixing said components together for an extended period of time to form a homogenous solution.

Optionally, the photoresist stripper further comprises other surfactants.

Optionally, the photoresist stripper further comprises other solvents.

Optionally, the photoresist stripper further comprises one or more corrosion inhibitors or chelating agents.

The invention also relates to a method for removing photoresist coatings from a substrate utilizing the composition of the invention.

The composition of this invention is suitable for use with all of the commonly employed positive and negative photoresists used in the semiconductor industry, including, but not limited to Kodak 747 and 752 negative photoresist; Hunt Chemical Waycoat Photoresist, both their positive HPR photoresist and their negative HNR 999 photoresist; Merck Chemical Selectilux photoresist, MacDermid negative photoresist; Shipley AZ series positive photoresist; KTI positive and negative photoresist; Dyna-Chem Thiokol OMR and OPR photoresist; and the like. The photoresists removed by the strippers of the present invention are preferably negative photoresists and most preferably the cyclicized rubber compositions such as cyclicized polyisoprene. Examples of such photoresist materials include Kodak KTFR® and Waycoat SC-100®.

Examples of substrates from which the stripping and cleaning compositions of the present invention remove photoresists without attacking the substrates themselves include metal substrates such as aluminum, titanium/tungsten, aluminum/silicon, aluminum/silicon/copper; and substrates such as silicon oxide, silicon nitride, and gallium/arsenide; and plastic substrates such as polycarbonate.

The method of removing a resist or other material from a substrate using the stripping compositions of the present invention involves contacting a substrate having a resist thereon with a stripping composition of the present invention for a time and at a temperature sufficient to remove the resist. The time and temperature are determined based on the particular material being removed from a substrate.

The method of cleaning a substrate using the cleaning compositions of the present invention involves contacting a substrate having photoresist, organometallic and metal oxide residue thereon with a cleaning composition of the present invention for a time and at a temperature sufficient to remove the residue.

The substrate is generally immersed in the cleaning composition. The time and temperature are determined based on the particular material being removed from a substrate. Generally, the temperature is in the range of from about ambient or room temperature to 100° C. and the contact time is from about 2 to 60 minutes.

The compositions of the present invention are preferably employed at temperatures of about 65° C. to about 100° C.

Organic Sulfonic Acid

A wide variety of sulfonic acid compounds may be use in the present invention. There are varieties of sulfonation reagents available, which make possible the conversion of a wide range of aromatics into sulfonic acids. The general mechanism for the reaction of an aromatic compound with sulfur trioxide involves an activated intermediate as shown in equation 1.

R—C₆H₅+SO₃→[R—C₆H₅—SO₃]*→R—C₆H₄SO₃H (1)

The sulfonic acids may be alkyl, aryl or alkylaryl. It is preferred that the groups of sulfonic acids are surfactants. It is further preferred that the sulfonic acids are aromatic.

Suitable sulfonic acids include, but are not limited to, benzene sulfonic acid, (C1 C20) alkylbenzene sulfonic acid, naphthalene sulfonic acid, (C1-C20) alkylnaphthalene sulfonic acid, (C7-C10)alkylaryl sulfonic acid, and the like. Preferred sulfonic acids include benzene sulfonic acid, tolyl sulfonic acid, hexylbenzene sulfonic acid, heptylbenzene sulfonic acid, octylbenzene sulfonic acid, decylbenzene sulfonic acid, dodecylbenzene sulfonic acid, tridecylbenzene sulfonic acid, quadecylbenzene sulfonic acid, hexadecylbenzene sulfonic acid, and benzyl sulfonic acid. It is further preferred that the sulfonic acid compound is one or more (C12-C20)alkylbenzene sulfonic acids. Mixtures of sulfonic acid compounds may be advantageously used in the present invention. The sulfonic acid compounds are generally commercially available from a variety of sources, such as Pilot Chemical and Aldrich Chemical may be used without further purification. Typically, the sulfonic acid compounds are used in the present compositions in an amount of from about 1% to about 90% wt, based on the total weight of the composition. It is preferred that the sulfonic acid compounds are used in an amount of from about 15% to about 65% wt, and more preferably from about 20% to about 50% wt.

### Alkanolamine

The alknaolamine compound suitable for use in the present invention can be represented by the chemical formula

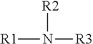

wherein R1 and R2 can be H, alkyl, aryl, alkylaryl, arylalkyl, alkyl alcohol, aryl alcohol, alkyaryl alcohol or arylalkyl alcohol and R3 is alkyl alcohol, aryl alcohol, alkyaryl alcohol or arylalkyl alcohol or the like.

Examples of suitable alkanolamines include monoethanolamine, diethanolamine, triethanolamine, tertiarybutyldiethanolamine isopropanolamine, 2-amino-1propanol,3-amino-1-propanol, isobutanolamine, 2-amino-2-ethoxyethanol, and 2-amino-2-ethoxy-propanol, 2-(2-hydroxylethylamino)ethanol, 2-(2-aminoethoxy)ethanol, N,N,N-tris(2-hydroxyethyl)-ammonia, isopropanolamine, 3-amino-1-propanol, 2-amino-1-propanol, 2-(N-methylamino)ethanol, 2-(2-aminoethylamino)ethanol, tris(hydroxymethyl)aminoethane, triethanolamine, trimethanolamine, triisopropanolamine or mixtures thereof.

### Amine Sulfonate/Sulfonamide as Anionic Surface-Active Agents

It is another objective of the present invention to provide a product by process of anionic surface-active agents for use in the present invention, whereby a cation derived from an alkanolamine (monoethanolamine, diethanolamine, triethanolamine, and the like) combine with the organic sulfonic acid described in the present invention to form an amine Sulfonate/sulfonamide as Anionic Surface-Active Agents.

The reactions can be illustrated as below:

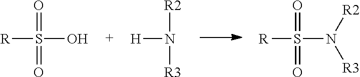

wherein R1 is H; R2 can be H, alkyl, aryl, alkylaryl, arylalkyl, alkyl alcohol, aryl alcohol, alkyaryl alcohol or arylalkyl alcohol and R3 is alkyl alcohol, aryl alcohol, alkyaryl alcohol or arylalkyl alcohol or the like.

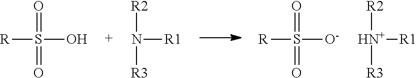

wherein R1 and R2 can be alkyl, aryl, alkylaryl, arylalkyl, alkyl alcohol, aryl alcohol, alkyaryl alcohol or arylalkyl alcohol and R3 is alkyl alcohol, aryl alcohol, alkyaryl alcohol or arylalkyl alcohol or the like.

The alkanolamine compound in the stripper composition is from about 0.01 to 1.0 mole ratio to the organic sulfonic acid.

For example, combining 1 mole of triethanolamine with 1 mole of dodecylbenzenesulfonic acid gives a product of Triethanolamine dodecylbenzenesulfonate. Such compound is available as Benzenesulfonic acid, C10-16 alkyl derivative, compounds with triethanolamine, under CAS #68584-25-8 from Pilot Chemical as CalSoft® T66.

However, the CalSoft® T66 contains water which is undesirable in the stripping composition due to high concentration of water will cause corrosion to the substrates.

It is another objective of the present invention to provide a stripper composition wherein the alkanolamine is presented in the reacted form.

### Organic Solvent

The solvent or solvent systems which are to be used must be materials which do not deter from the stripping effectiveness of the sulfonic acid and should be miscible with the one or more sulfonic acids. The solvent is also present to reduce the viscosity and to render the sulfonic acid more readily removed from the substrate during rinsing the substrate in water.

The preferred organic solvents employed generally contain at least 8 carbon atoms and have boiling points starting at about 135° C.

Such organic solvents are available from refined petroleum product companies such as Shell Chemical Co., ExxonMobil Chemical Company.

Preferred aromatic solvents of the present invention have initial boiling points of about 120° C. at 760 mm Hg pressure, and a dry point of about 170° C. to about 280° C.

The compositions of the present invention may further include one or more additional corrosion inhibitors, other organic solvents, surfactants and the like.

### Corrosion Inhibitors

Suitable corrosion inhibitors useful in the present invention include, but are not limited to, catechol; (C1 C6)allylcatechol such as methylcatechol, ethylcatechol and tert-butylcatechol; benzotriazole; (CC C10) alkylbenzotriazoles; gallic acid; gallic acid esters such as methyl gallate and propyl gallate; and the like. It is preferred that the corrosion inhibitor is catechol, (C1-C6) alkylcatechol, benzotriazole or (C1-C10) alkylbenzotriazoles. When such corrosion inhibitors are used they are typically present in an amount in the range of about 0.01 to 10% wt, based on the total weight of the stripping composition.

### Suitable Organic Solvents

Suitable nonpolar, organic solvents for use in the composition and method of this invention include aromatic organics containing 6 to 14 carbon atoms, such as benzene, and the like; aliphatic organics containing one to 30 carbon atoms, such as n-pentane, n-octane, dodecane, and the like; monoalkyl-substituted aromatic organics, such as toluene, ethyl benzene, cumene, octylbenzene, decylbenzene and dodecylbenzene; dialkyl substituted organics containing eight to 20 carbon atoms, such as the ortho, meta and para isomers of xylene and diethylbenzene; trialkyl-substituted aromatic organics containing 9 to 20 carbon atoms, such as the 1,2,3-; 1,2,4- and 1,3,5-isomers of 10 trimethyl and triethylbenzene.

Suitable polar organic solvents include aliphatic ketones containing three to carbon atoms, such as acetone, methylethylketone and methylisobutylketone; monoalkyl ethers of ethylene glycol containing three to 10 carbon atoms, such as ethoxyethanol and butoxyethanol; carboxylic acids containing one to four carbon atoms, such as acetic and maleic acid; formamide; N,N-dialkylalkanonylamides containing three to 10 carbon atoms, such as dimethylformamide and dimethylacetamide; N-alkyl lactams containing six to 12 carbon atoms, such as N-methylpyrrolidone; cyclic aliphatic sulfones containing four to 6 carbon atoms, such as tetramethylenesulfone; and the like. The preferred nonpolar, organic solvents are xylene, toluene, isopropylnapthalene, and decalin. The preferred polar solvents are dimethyl-formamide, N-methylpyrollidone, and sulfolane. If present, the solvent desirably comprises from about one to about 60 weight percent of the composition.

### Suitable Surfactants

Suitable surfactants are selected from nonionic types, cationic types and anionic types of surfactants. Suitable surfactants include poly(vinyl alcohol), poly (ethyleneimine) and any of the surfactant compositions classified as anionic, cationic, nonionic, amphoteric, and silicone-based. Preferred surfactants are poly(vinyl alcohol), poly(ethyleneimine) and epoxy-polyamide compound. Preferably, a surfactant is present in the cleaning composition of the present invention, typically in the amount of about 10 ppm to 5% by weight based on the total weight of the cleaning composition.

A preferred composition of the present invention contains about 30%-50% by weight of dodecylbenzene sulfonic acid, about 1%-10% by weight of triethanolamine, and about 50%-70% by weight of organic containing at 5 least 8 carbon atoms and preferably, Shell Sol 150, ShellSol™ 150ND, Solvesso™ 150, ExxonMobil 150 Aromatic fluid and the like.

The present invention discloses a photoresist stripper for removing positive and negative tone photoresist, bonding adhesive, ink mark and post etch residue etc. from semiconductor substrates. The photoresist stripper comprises from about 1% to 70% of one or more organic sulfonic acids with a structure of

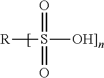

where R can be alkyl, substituted alkyl, aryl, substituted aryl and alkylaryl, and n is 1 or higher; and from 0.1% to 70% of one or more alkanolamine; and from about 0.1% to 10% of one or more corrosion inhibitor and one or more halogen free organic solvents, wherein the preferred halogen free organic solvent has a boiling point above 120° C.

### DETAILED DESCRIPTION OF THE INVENTION

Most of the commercially available sulfonic acid contains a residual amount of sulfuric acid and sulfur trioxide from its sulfonation reaction of sulfur trioxide with the representative organic compound.

Pilot Chemical produces dodecylbenzene sulfonic acid for use in detergent industry. In section 2 of the Material Safety Data Sheet (MSDS), it listed the amounts of sulfuric acid and sulfur trioxide presence in the product.

2. COMPOSITION/INFORMATION ON INGREDIENTS

| Component | CAS-No | Weight % | OSHA PEL |
|---|---|---|---|
| Benzenesulfonic acid, C10- | 68584-22-5 | 97 | — |
| 16-alkyl derivatives | | | |
| Benzene, C10-16-alkyl | 68648-87-3 | 1 | — |
| derivatives | | | |
| Sulfuric acid | 7664-93-9 | 1 | TWA: 1 mg/m3 |
| Sulfur dioxide | 7446-09-5 | 1 | TWA: 2 ppm |
| | | | TWA: 5 mg/m3 |
| | | | STEL: 15 mg/m3 |
| | | | STEL: 5 ppm |

When the sulfonic acid is formulated with other solvents for the use in photoresist stripping and cleaning processes during the manufacturing of semiconductor devices, the presence of the minute amount of the sulfuric acid and sulfur trioxide will cause damage to the metal substrate surface.

For example, the dodecylbenzenesulfonic acid product specification from Pilot Chemical shows the product to contain 1.0% sulfuric and 1% sulfur trioxide. Mixing dodecylbenzene sulfonic acid with solvent system illustrated by the prior art, without allowing sufficient time to reduce the sulfuric acid in the stripper solution, will cause higher attack of the aluminum.

Alkanolamine in the present invention serves the purpose of neutralizing the acids to reduce the acid in the stripper solution and simultaneously work as an anionic surface active agent.

The heat generated from the neutralization of alkanolamine with the organic sulfonic acid during the mixing of the stripper solution also aids the dissolution of corrosion inhibitor, such as catechol, gallic acid etc. to the stripper solution forming a homogenous blend.

The following examples of stripping compositions and preparation are provided to further illustrate the present invention and are not intended to limit the scope of the present invention for removing a resist from a substrate are set forth in Table I below.

TABLE I

| | Dodecylbenzene Sulfonic | | | Triethanolamine | | | Exxon Aromatic A- | | | | | |
|---|---|---|---|---|---|---|---|---|---|---|---|---|
| | Acid (MW = 326.5) | | | (MW = 148.20) | | | 150 solvent | | Catechol | | Total | |
| | Mole | Weight | Wt % | Mole | Weight | Wt % | Weight | Wt % | Weight | Wt % | Weight | Wt % |
| A | 1.2 | 391.8 | 36.84% | 0.5 | 74.1 | 6.97% | 587.7 | 55.26% | 10 | 0.94% | 1063.6 | 100.00% |
| B | 1.3 | 424.45 | 37.06% | 0.5 | 74.1 | 6.47% | 636.675 | 55.59% | 10 | 0.87% | 1145.23 | 100.00% |
| C | 1.4 | 457.1 | 37.26% | 0.5 | 74.1 | 6.04% | 685.65 | 55.89% | 10 | 0.82% | 1226.85 | 100.00% |
| D | 0.65 | 212.23 | 32.53% | 0.1 | 14.82 | 2.27% | 424.45 | 65.05% | 1 | 0.15% | 652.495 | 100.00% |
| E | 0.65 | 212.23 | 30.41% | 0.4 | 59.28 | 8.49% | 424.45 | 60.81% | 2 | 0.29% | 697.955 | 100.00% |
| F | 0.65 | 212.23 | 35.86% | 0.4 | 59.28 | 10.02% | 318.338 | 53.79% | 2 | 0.34% | 591.843 | 100.00% |
| G | 0.65 | 212.23 | 27.95% | 0.8 | 118.6 | 15.62% | 424.45 | 55.90% | 4 | 0.53% | 759.235 | 100.00% |
| H | 0.65 | 212.23 | 32.49% | 0.8 | 118.6 | 18.15% | 318.338 | 48.74% | 4 | 0.61% | 653.123 | 100.00% |
| I | 0.65 | 212.23 | 26.77% | 1 | 148.2 | 18.69% | 424.45 | 53.53% | 8 | 1.01% | 792.875 | 100.00% |
| J | 0.65 | 212.23 | 30.90% | 1 | 148.2 | 21.58% | 318.338 | 46.35% | 8 | 1.16% | 686.763 | 100.00% |
| K | 0.65 | 212.23 | 32.58% | 0.1 | 14.82 | 2.27% | 424.45 | 65.15% | 0 | 0.00% | 651.495 | 100.00% |
| L | 1.4 | 457.1 | 37.56% | 0.5 | 74.1 | 6.09% | 685.65 | 56.35% | 0 | 0.00% | 1216.85 | 100.00% |
| M | 0.65 | 212.23 | 32.69% | 0.8 | 118.6 | 18.26% | 318.338 | 49.04% | 0 | 0.00% | 649.123 | 100.00% |
| N | 0.65 | 212.23 | 35.98% | 0.4 | 59.28 | 10.05% | 318.338 | 53.97% | 0 | 0.00% | 589.843 | 100.00% |
| O | 0.65 | 212.23 | 32.58% | 0.1 | 14.82 | 2.27% | 424.45 | 65.15% | 0 | 0.00% | 651.495 | 100.00% |

In another embodiment of the present invention discloses the method of preparation of the photoresist stripper.

A mixture of organic sulfonic acid and organic solvent is mixed with mechanical agitation in a mixing tank to a homogenous solution. Alkanolamine is gradually added to the mixture with continuous agitation. The temperature of the solution rises slowly to about 70° C. The temperature rise is moderated with the rate of addition of the alkanolamine.

The corrosion inhibitor, 1,2 dihydroxybenzene (catechool) is dispersed in a mixture of ExxonMobil 150 Aromatic fluid (solvent) and dodecylbenzenesulfonic acid. Triethanolamine is gradually added to the mixtures with continuous agitation. The temperature of the solution rises slowly to about 70° C. The dispersion becomes a homogenous solution.

Solutions A to O are non-limiting examples represent preferred forms and best modes contemplated by the inventor for practice of his invention, as well as illustrating the results obtained through its use.

Examples illustrating the removal of a resist from a substrate under varying conditions using the stripping compositions of the present invention are described further below. Thereafter, examples illustrating the removal of etching residue from a substrate are set forth. The following examples are provided to further illustrate the present invention and are not intended to limit the scope of the present invention.

These results show that the photoresist stripper composition produced by the invention is suitable for use under production conditions encountered in the manufacture of integrated circuits without damage the substrate metal surface.

Substitution of other solvents and organic sulfonic acids as described above in the above Examples gives similar advantageous results. It should now be apparent to those skilled in the art that a novel method of manufacturing photoresist stripping composition and method capable of achieving the stated objects of this invention has been provided. At least equivalent results are obtained with the composition and method of this invention as compared with results achieved utilizing the sulfonic acid, phenol and chlorinated organic solvent photoresist stripping composition in general use in the manufacture of integrated circuits. No attack on aluminum metallurgy or silicon dioxide insulators on silicon wafers is observed with the present invention. It should further be apparent to those skilled in the art that various changes in form and details of the invention as described may be made. It is intended that such changes be included within the spirit and scope of the claims appended hereto.

All references, patents, patent applications referred to in this application are herein being incorporated by reference in their entirety.

What is claimed is:

1. A composition for removing a positive or negative tone photoresist, bonding adhesive, ink mark, and/or post etch residue from a semiconductor substrate, the composition comprising:
a) from about 1% to 70% by weight of one or more organic sulfonic acids having a general formula: 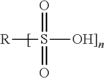
wherein n≧1, and R is independently an alkyl group, substituted alkyl group, aryl group, substituted aryl group, or an arylalkyl group; and
b) from about 0.1% to 70% by weight of one or more alkanolamine with the structure of 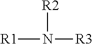
wherein R1 and R2 can be H, alkyl, aryl, alkylaryl, arylalkyl, alkyl alcohol, aryl alcohol, alkaryl alcohol or arylalkyl alcohol and R3 is alkyl alcohol, aryl alcohol, alkylaryl alcohol or arylalkyl alcohol or the like.
c) Optionally, one or more halogen-free organic solvents

2. The composition of claim 1, wherein the one or more organic sulfonic acid comprises benzenesulfonic acid, C₁-C₂₀ alkylbenzenesulfonic acid, naphthalene sulfonic acid, C₁-C₂₀ alkylnaphthalene sulfonic acid, C₇-C₁₀ alkylaryl sulfonic acid, or mixtures thereof.

3. The composition of claim 2, wherein the C₁-C₂₀ alkybenzenesulfonic acid comprises hexylbenzenesulfonic acid, heptylbenzenesulfonic acid, octylbenzenesulfonic acid, decylbenzenesulfonic acid, dodecylbenzenesulfonic acid, tridecylbenzenesulfonic acid, quaddecylbenzenesulfonic acid, hexadecylbenzenesulfonic acid, or mixtures thereof.

4. The composition of claim 1, wherein the alkanolamine is selected from the group consisting of triethanolamine, triisopropanolamine.

5. The composition of claim 1, further comprising a corrosion inhibitor wherein is selected from a group comprising of comprises catechol; (C₁-C₆) allylcatechol such as methylcatechol, ethylcatechol, tert-butylcatechol; benzotriazole; (C₁-C₁₀) alkylbenzotriazoles; gallic acid; gallic acid esters; methyl gallate; propyl gallate, or mixtures thereof.

6. The composition of claim 5, wherein the amount of the corrosion inhibitor is in the range of about 0.01 to 10% by weight.

7. The composition of claim 1, further comprising a chelating agent.

8. The composition of claim 1, further comprising about 10 ppm to 5% by weight a surfactant.

9. The composition of claim 8, wherein the surfactant comprises nonionic, cationic, amphoteric, anionic surfactants or mixtures thereof.

10. The composition of claim 9, wherein the surfactant is a silicone based surfactant.

11. The composition of claim 9, wherein the surfactant is poly(vinyl alcohol), poly (ethyleneimine), epoxy-polyamide compound or mixtures thereof.

12. The composition of claim 1, wherein the organic solvent is present in the range of about 1 to 70% by weight.

13. A method of cleaning semiconductor substrates comprising the steps of:
a) providing a substrates having surface comprising a positive or negative tone photoresist, bonding adhesive, ink mark, and/or post etch residue from a semiconductor substrate comprising the steps of:
b) contacting the surface of the substrate with an effective amount of the solution comprising
i) from about 1% to 70% by weight of one or more organic sulfonic acids having a general formula: 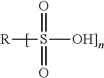
wherein n≧1, and R is independently an alkyl group, substituted alkyl group, aryl group, substituted aryl group, or an arylalkyl group; and
ii) from about 0.1% to 70% by weight of one or more alkanolamine with the structure of 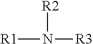
iii) wherein R1 and R2 can be H, alkyl, aryl, alkylaryl, arylalkyl, alkyl alcohol, aryl alcohol, alkyaryl alcohol or arylalkyl alcohol and R3 is alkyl alcohol, aryl alcohol, alkyaryl alcohol or arylalkyl alcohol or the like.
iv) optionally, one or more halogen-free organic solvents
c) for a temperature and for a time sufficient to remove the photoresist from the substrate.

14. The method of claim 13, further comprising rinsing the substrate with deionized water.

15. The method of claim 13, wherein the one or more organic sulfonic acid comprises benzenesulfonic acid, C₁-C₂₀ alkylbenzenesulfonic acid, naphthalene sulfonic acid, C₁-C₂₀ alkylnaphthalene sulfonic acid, C₇-C₁₀ alkylaryl sulfonic acid, or mixtures thereof.

16. The method of claim 15, wherein the C₁-C₂₀ alkylbenzenesulfonic acid comprises hexylbenzenesulfonic acid, heptylbenzenesulfonic acid, octylbenzenesulfonic acid, decylbenzenesulfonic acid, dodecylbenzenesulfonic acid, tridecylbenzenesulfonic acid, quaddecylbenzenesulfonic acid, hexadecylbenzenesulfonic acid, or mixtures thereof.

17. The method of claim 13, wherein the alkanolamine is selected from the group consisting of triethanolamine, triisopropanolamine.

18. The method of claim 13, further comprising a corrosion inhibitor wherein is selected from a group comprising of comprises catechol; (C₁-C₆) allylcatechol such as methylcatechol, ethylcatechol, tert-butylcatechol; benzotriazole; (C₁-C₁₀) alkylbenzotriazoles; gallic acid; gallic acid esters; methyl gallate; propyl gallate, or mixtures thereof.

19. The method of claim 18, wherein the amount of the corrosion inhibitor is in the range of about 0.01 to 10% by weight.

20. The method of claim 13, further comprising a chelating agent.

21. The method of claim 13, further comprising about 10 ppm to 5% by weight a surfactant.

22. The method of claim 21, wherein the surfactant comprises nonionic, cationic, amphoteric, anionic surfactants or mixtures thereof.

23. The method of claim 21, wherein the surfactant is a silicone based surfactant.

24. The method of claim 21, wherein the surfactant is poly(vinyl alcohol), poly (ethyleneimine), epoxy-polyamide compound or mixtures thereof.
